(19) United States
(12) Patent Application Publication
(10) Pub. No.: US 2017/0133402 A1
(43) Pub. Date: May 11, 2017

(54) AN ARRAY SUBSTRATE AND A DISPLAY DEVICE

(71) Applicant: Boe Technology Group Co., Ltd., Beijing (CN)

(72) Inventors: Ce Ning, Beijing (CN); Chunwei Wu, Beijing (CN); Yuting Zhang, Beijing (CN)

(21) Appl. No.: 14/768,000

(22) PCT Filed: Jan. 5, 2015
(86) PCT No.: PCT/CN2015/070089

§ 371 Date: Aug. 14, 2015

(30) Foreign Application Priority Data
Sep. 19, 2014 (CN) 201410484505.X

(51) Int. Cl. H01L 27/12

(52) U.S. Cl. CPC H01L 27/124; H01L 27/1248

(57) ABSTRACT

One embodiment of the present disclosure provides an array substrate, comprising: a gate line, a data line, and a common electrode layer electrically insulated from the gate line and the data line, wherein there is at least one overlapping area between the common electrode layer and the gate line, and/or, there is at least one overlapping area between the common electrode layer and the data line; moreover, the common electrode layer comprises a hollow structure part located in the at least one overlapping area, and the hollow structure part located in the overlapping area comprises at least one hollow area.

### RELATED APPLICATIONS

This application is the U.S. national phase entry of PCT/CN2015/070089, with an international filing date of Jan. 5, 2015, which claims priority to Chinese Patent Application No. 201410484505.X, filed on Sep. 19, 2014, the entire disclosures of which are incorporated herein by reference.

### FIELD OF THE DISCLOSURE

The present disclosure relates to the field of display technology, particularly to an array substrate and a display device.

### BACKGROUND OF THE DISCLOSURE

When an array substrate not only comprises a gate line and a data line, but also comprises a common electrode layer electrically insulated from the gate line and the data line, a parasitic capacitance C_{gc} may be formed between the common electrode layer and the gate line. Further, a parasitic capacitance C_{dc} may be formed between the common electrode layer and the data line.

At present, there may or may not be an overlapping area between the electrically insulated common electrode layer and the gate line When there is an overlapping area between the common electrode layer and the gate line, the capacitance value of C_{gc} is relatively large. Similarly, when there is an overlapping area between the electrically insulated common electrode layer and the data line, the capacitance value of C_{dc} is relatively large.

When the capacitance value of C_{gc} is relatively large, the electric quantity consumed for charging C_{gc} is also relatively large, such that the power consumption of the array substrate is relatively large. Moreover, when the capacitance value of C_{gc} is relatively large, the signal transmitted on the gate line may result in crosstalk with the signal applied on the common electrode layer, thereby resulting in display defect. Similarly, when the capacitance value of C_{dc} is relatively large, the problems of relatively large power consumption and display defect may also occur.

To sum up, at present, when there is an overlapping area between the common electrode layer and the gate line, the capacitance value of C_{gc} is relatively large. When there is an overlapping area between the common electrode layer and the data line, the capacitance value of C_{dc} is relatively large.

### SUMMARY OF THE DISCLOSURE

The embodiment of the present disclosure provides an array substrate and a display device for solving the problem that the capacitance values of C_{gc} and/or C_{dc} are relatively large in the prior art.

In one aspect, the embodiment of the present disclosure provides an array substrate, comprising: a gate line, a data line, and a common electrode layer electrically insulated from the gate line and the data line, wherein there is at least one overlapping area between the common electrode layer and the gate line, and/or, there is at least one overlapping area between the common electrode layer and the data line.

The common electrode layer comprises a hollow structure part located in the at least one overlapping area, and the hollow structure part located in the overlapping area comprises at least one hollow area.

Optimally, the hollow structure part located in the overlapping area comprises a plurality of hollow areas arranged in a matrix.

Optimally, the hollow structure part located in the overlapping area is in a grid structure.

Optimally, each of the hollow areas is in a circular shape.

Optimally, the hollow structure part located in the overlapping area comprises one hollow area in a rectangular shape.

Optimally, for the hollow area comprised by the hollow structure part located in the overlapping area: for any point on the frame of the hollow area, the minimum value of the distance from it to the frame of the overlapping area is not less than 2 μm.

Optimally, the common electrode layer, the gate line and the data line are located in different layers respectively, the array substrate further comprises: intermediate layers located between the film where the gate line locates and the common electrode layer, and between the film where the data line locates and the common electrode layer; wherein the intermediate layers comprise a passivation layer and/or a resin layer, the material of the passivation layer comprises one or more of silicon oxide and silicon nitride.

Optimally, the value of the thickness of the intermediate layer is not less than 2 μm.

In a second aspect, the embodiment of the present disclosure provides a display device, comprising an array substrate as stated in the embodiment of the present disclosure.

In the embodiment of the present disclosure, the array substrate comprises a gate line, a data line, and a common electrode layer electrically insulated from the gate line and the data line, wherein there is at least one overlapping area between the common electrode layer and the gate line, and/or, there is at least one overlapping area between the common electrode layer and the data line; moreover, the common electrode layer comprises a hollow structure part located in the at least one overlapping area, and the hollow structure part located in the overlapping area comprises at least one hollow area.

Compared with the prior art, the common electrode layer of the embodiment of the present disclosure arranges a hollow structure part with hollow areas in the at least one overlapping area, thereby reducing the actual area of the overlapping area between the common electrode layer and the gate line and/or the data line, and reducing the capacitance values of C_{gc} and/or C_{dc}.

### BRIEF DESCRIPTION OF DRAWINGS

FIG. 1a to FIG. 1d are schematic views of structure of a hollow structure part located in the overlapping area in the embodiment of the present disclosure;

FIG. 2 is a vertical view of an array substrate comprised by the high advanced dimension switch (HADS) mode display device in the embodiment of the present disclosure.

### DETAILED DESCRIPTION OF THE DISCLOSURE

In order to explain the solution of the embodiment of the present disclosure clearly, next, the embodiment of the present disclosure will be further described specifically in combination with the drawings of the description.

It should be noted that the thickness and shape of the respective films in the drawings do not reflect the real proportion, and are only for explaining the contents of the present disclosure schematically.

Optimally, the embodiment of the present disclosure provides an array substrate, comprising: a gate line, a data line, and a common electrode layer electrically insulated from the gate line and the data line, wherein there is at least one overlapping area between the common electrode layer and the gate line, and/or, there is at least one overlapping area between the common electrode layer and the data line.

The common electrode layer comprises a hollow structure part located in the at least one overlapping area, and the hollow structure part located in the overlapping area comprises at least one hollow area.

In some implementations, the common electrode layer of the embodiment of the present disclosure arranges a hollow structure part with hollow areas in the at least one overlapping area, thereby reducing the actual area of the overlapping area between the common electrode layer and the gate line and/or the data line.

Therefore, the embodiment of the present disclosure can reduce the capacitance values of C_{gc} and/or C_{dc}, thereby reducing the power consumption of the array substrate to a certain extent, and avoiding occurrence of display defect.

Optimally, the common electrode layer comprises a hollow structure part located in each of the overlapping areas.

In some implementations, in the case that the specific structure of the hollow structure part located in the overlapping area is unchanged, the larger the number of the overlapping areas arranged with the hollow structure part is, the smaller the actual area of the overlapping area between the common electrode layer and the gate line and/or the data line is; and the smaller the capacitance value of C_{gc} and/or C_{dc} is. Hence, in the case that the specific structure of the hollow structure part located in the overlapping area is unchanged, and when the common electrode layer comprises a hollow structure part located in each of the overlapping areas, the actual area of the overlapping area between the common electrode layer and the gate line and/or the data line is minimum, and the capacitance value of C_{gc} and/or C_{dc} is minimum.

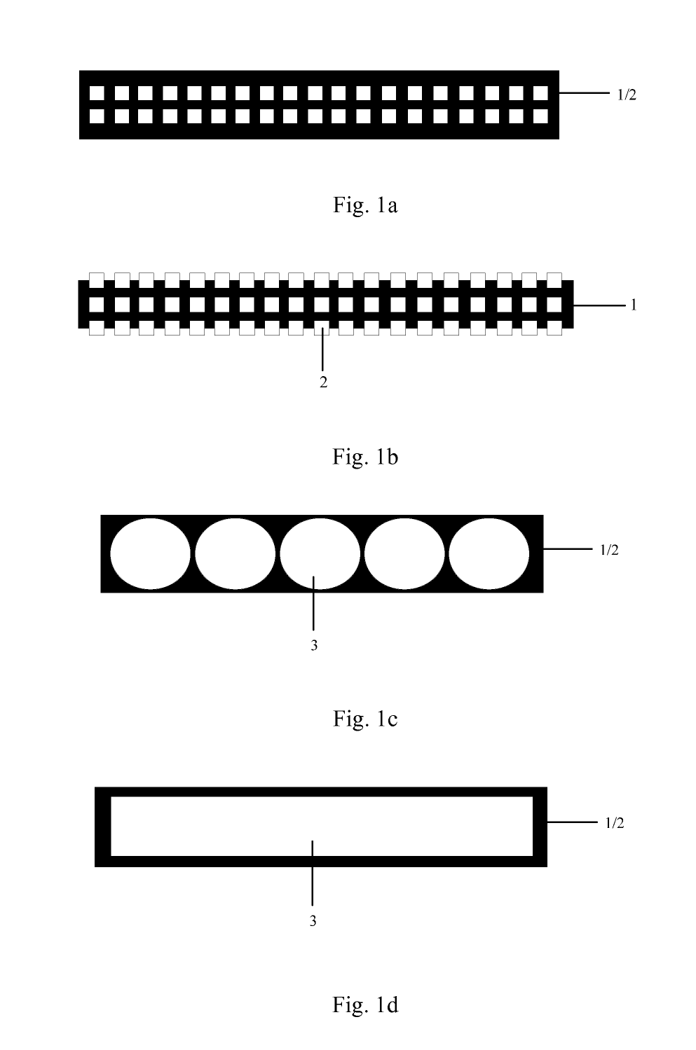

The size of the hollow structure part located in the overlapping area may or may not match with the size of the corresponding overlapping area. For example, take the hollow structure part located in one of the overlapping areas as the example, as shown in FIG. 1a. The size of the hollow structure part 2 located in the overlapping area 1 matches with the size of the corresponding overlapping area 1. As shown in FIG. 1b, the size of the hollow structure part 2 located in the overlapping area 1 does not match with the size of the corresponding overlapping area 1. Here, the size of the size of the hollow structure part 2 located in the overlapping area 1 is slightly larger than the size of the corresponding overlapping area 1.

It should be noted that in the embodiment of the present disclosure, the hollow structure part located in the overlapping area only needs to meet the requirement of comprising at least one hollow area. While the specific number, shape, size, and arrangement manner of the hollow areas comprised in the hollow structure part located in the overlapping area can be set arbitrarily based on needs.

Optimally, the hollow structure part located in the overlapping area may comprise one or more hollow areas. In some implementations, in the case that the size of the hollow area comprised in the hollow structure part located in the overlapping area is unchanged, the larger the number of the overlapping areas arranged with the hollow structure part are, the smaller the actual area of the overlapping area between the common electrode layer and the gate line and/or the data line is; and the smaller the capacitance value of C_{gc} and/or C_{dc} is.

Optimally, the shape of the hollow area comprised in the hollow structure part located in the overlapping area may be either a regular shape or an irregular shape. In some implementations, when the shape of the hollow area comprised in the hollow structure part located in the overlapping area is a regular shape, the fabricating complexity thereof is relatively low.

Optimally, the size of the hollow area comprised in the hollow structure part located in the overlapping area can be set arbitrarily based on needs. In some implementations, in the case that the number of the hollow areas comprised in the hollow structure part located in the overlapping area is unchanged, the larger the hollow area comprised in the hollow structure part located in the overlapping area, the smaller the actual area of the overlapping area between the common electrode layer and the gate line and/or the data line; and the smaller the capacitance value of C_{gc} and/or C_{dc}.

Optimally, when the hollow structure part located in the overlapping area comprises a plurality of hollow areas, the plurality of hollow areas may be arranged either regularly or irregularly.

In some implementations, when the plurality of hollow areas comprised in the hollow structure part located in the overlapping area are arranged regularly, the fabricating complexity thereof is relatively low.

Next, the number of the hollow areas comprised in the hollow structure part located in the overlapping area is taken as the basis for classification to explain several optimal implementing modes of the hollow areas comprised in the hollow structure part located in the overlapping area.

I. The Hollow Structure Part Located in the Overlapping Area Comprises a Plurality of Hollow Areas.

Optimally, the hollow structure part located in the overlapping area comprises a plurality of hollow areas arranged in a matrix. In some implementations, when the plurality of hollow areas comprised in the hollow structure part located in the overlapping area are arranged in a matrix, the fabricating complexity thereof is relatively low.

Optimally, as shown in FIG. 1a, the hollow structure part 2 located in the overlapping area 1 is in a grid structure. In some implementations, when the hollow structure part located in the overlapping area is in a grid structure, the fabricating complexity thereof is relatively low.

Optimally, as shown in FIG. 1c, the respective hollow areas 3 comprised in the hollow structure part 2 located in the overlapping area 1 are in a circular shape. In some implementations, the gate line and the data line are generally in a strip shape. When there is an overlapping area between the common electrode layer and the gate line and/or the data line, the overlapping area between the common electrode layer and the gate line and/or the data line is generally in a rectangular shape. Hence, compared with other shapes of the hollow area, when the respective hollow areas are in a circular shape, it can be ensured that the actual area of the overlapping area between the common electrode layer and the gate line and/or the data line is relatively small, and the capacitance value of C_{gc} and/or C_{dc} is relatively small.

II. The Hollow Structure Part Located in the Overlapping Area Comprises One Hollow Area.

Optimally, as shown in FIG. 1d, the hollow structure part 2 located in the overlapping area 1 comprises one hollow area 3 in a rectangular shape. In some implementations, the gate line and the data line are generally in a strip shape. When there is an overlapping area between the common electrode layer and the gate line and/or the data line, the overlapping area between the common electrode layer and the gate line and/or the data line is generally in a rectangular shape. Hence, compared with other shapes of the hollow area, when the hollow area is in a rectangular shape, it can be ensured that the actual area of the overlapping area between the common electrode layer and the gate line and/or the data line is relatively small, the he capacitance value of C_{gc} and/or C_{dc} is relatively small. In addition, the fabricating complexity is also relatively low.

Optimally, for any point on the frame of the hollow area, the minimum value of the distance from it to the frame of the overlapping area is not less than 2 μm. In some implementations, for any point on the frame of the hollow area, the minimum value of the distance from it to the frame of the overlapping area is not less than 2 μm and the occurrence of light leakage can be avoided to a certain extent.

Optimally, the common electrode layer, the gate line and the data line are located in different layers respectively, and the array substrate further comprises: intermediate layers located between the film where the gate line locates and the common electrode layer, and between the film where the data line locates and the common electrode layer; wherein the intermediate layers comprise a passivation layer and/or a resin layer, the material of the passivation layer comprises one or more of silicon oxide and silicon nitride.

In some implementations, by fabricating intermediate layers between the film where the gate line locates and the common electrode layer, and between the film where the data line locates and the common electrode layer, the distance between the film where the data line locates and the common electrode layer can be increased; and the distance between the film where the gate line locates and the common electrode layer can be increased.

However, it should be noted that the larger the distance between the common electrode layer and the film where the gate line is located, the smaller the capacitance value of C_{gc} is. Similarly, the larger the distance between the common electrode layer and the film where the data line is located, the smaller the capacitance value of C_{dc} is. Hence, the embodiment of the present disclosure can reduce the capacitance values of C_{gc} and C_{dc}. Therefore, the power consumption of the array substrate can be reduced to a certain extent, and the occurrence of display defect can be avoided.

It should be noted that according to the difference in film order of the common electrode layer, the film where the gate line is located and the film where the data line is located, the intermediate layer located between the film where the gate line is located and the common electrode layer, and the intermediate layer located between the film where the data line is located and the common electrode layer may be the same film, and may also be different films.

For example, when the common electrode layer is located between the film where the gate line is located and the film where the data line is located, the intermediate layer (the first intermediate layer) located between the film where the gate line is located and the common electrode layer, and the intermediate layer (the second intermediate layer) located between the film where the data line is located and the common electrode layer are different films.

When the film where the gate line locates is located between the common electrode layer and the film where the data line is located, and an intermediate layer is arranged between the film where the gate line is located and the common electrode layer, the intermediate layer located between the film where the gate line is located and the common electrode layer, and the intermediate layer located between the film where the data line is located and the common electrode layer are the same film.

When the film where the data line is located between the common electrode layer and the film where the gate line is located, and an intermediate layer is arranged between the film where the data line is located and the common electrode layer, the intermediate layer located between the film where the gate line is located and the common electrode layer, and the intermediate layer located between the film where the data line is located and the common electrode layer are the same film.

In specific implementations, the thickness of the intermediate layer can be set based on application needs. For example, when the thickness of the intermediate layer is set, the effect of reducing the capacitance values of C_{gc} and C_{dc} and the thickness of the array substrate are considered comprehensively.

Optimally, the film number of the passivation layer and/or the resin layer can be increased or decreased to obtain an intermediate layer with a preset thickness.

Optimally, the value of the thickness of the intermediate layer is not less than 2 μm.

In some implementations, the value of the thickness of the intermediate layer is not less than 2 μm, it can ensure a better effect of reducing the capacitance values of C_{gc} and C_{dc}.

It should be noted that the array substrate in the embodiment of the present disclosure may be any array substrate that comprises: a gate line, a data line, and a common electrode layer electrically insulated from the gate line and the data line, wherein there is at least one overlapping area between the common electrode layer and the gate line, and/or, there is at least one overlapping area between the common electrode layer and the data line. For example, the array substrate may be comprised by a HADS mode display device, or, an array substrate comprised by an innovative advanced dimension switch (IADS) mode display device.

### EMBODIMENT

Next, the structure of a pixel unit comprised by the array substrate in the HADS mode display device is taken as an example to explain the solution of the embodiment of the present disclosure.

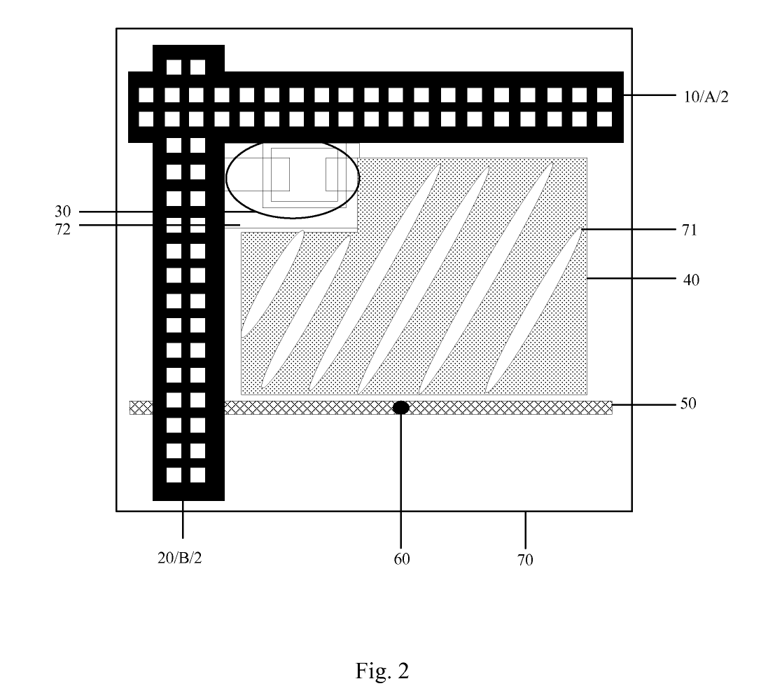

As shown in FIG. 2, the array substrate of the HADS mode display device comprises: a gate line 10 and a data line 20 intersected with each other to define a pixel unit, a thin film transistor (TFT) 30 and a pixel electrode 40 located in the pixel unit and electrically connected with each other, a common electrode line 50 arranged in the same layer as the gate line 10 and insulated from each other, and a common electrode layer 70 electrically connected with the common electrode line 50 through a via hole 60. There is an overlapping area A between the electrically insulated common electrode layer 70 and the gate line 10, and there is an overlapping area B between the electrically insulated common electrode layer 70 and the data line 20.

The common electrode layer 70 comprises a plurality of hollow areas 71 located exactly above the pixel electrode 40, so that an edge electric field can be formed between the common electrode layer 70 and the pixel electrode 40. The common electrode layer 70 comprises a hollow area 72 located exactly above the TFT 30, so as to avoid the common electrode layer 70 from interfering the TFT 30. In addition, the common electrode layer 70 further comprises hollow structure parts 2 with hollow areas located in the overlapping area A and the overlapping area B, and the hollow structure parts 2 located in the overlapping area A and the overlapping area B are both in a grid structure.

In some implementations, there is an overlapping area between the electrically insulated common electrode layer and the gate line, and there is an overlapping area between the electrically insulated common electrode layer and the data line. Hence, the capacitance values of C_{gc} and C_{dc} are relatively large and since the common electrode layer arranges a hollow structure part in a grid structure in this overlapping area, the actual area of the overlapping area between the common electrode layer and the gate line can be reduced; and the actual area of the overlapping area between the common electrode layer and the data line can be reduced, thereby reducing the capacitance values of C_{gc} and C_{dc}.

Optimally, based on the same inventive concept, the embodiment of the present disclosure provides a display device, comprising an array substrate provided by the embodiment of the present disclosure.

In some implementations, the capacitance values of C_{gc} and C_{dc} in the array substrate in the embodiment of the present disclosure are reduced, such that the power consumption of the array substrate, and the occurrence probability of the problem of display defect are reduced to a certain extent. Therefore, the power consumption of the array substrate, and the occurrence probability of the problem of display defect of the display device comprising the array substrate in the embodiment of the present disclosure are also reduced to a certain extent.

Optimally, the display device may be any product or component with the display function, such as a liquid crystal panel, electronic paper, an OLED panel, a mobile phone, a tablet computer, a television, a display, a laptop, a digital photo frame, or a navigator.

Although the preferred embodiments of the present disclosure have been described, the skilled person in the art, once having learned the basic inventive concept, can make additional variations and modifications to these embodiments. So, the claims attached intend to be construed as comprising the preferred embodiments and all the variations and modifications falling within the scope of the present disclosure.

As is apparent to the skilled person in the art, various modifications and variations to the present disclosure may be made without departing from the spirit and scope of the present disclosure. Therefore these modifications and variations of the present disclosure belong to the scope of the claims of the present disclosure and the equivalent technologies thereof, the present disclosure also intends to contain these modifications and variations.

1-9. (canceled)

10. An array substrate, comprising: a gate line, a data line, and a common electrode layer electrically insulated from the gate line and the data line, wherein:
the common electrode layer comprises a hollow structure part located in at least one overlapping area between the common electrode layer and the gate line, and/or located in at least one overlapping area between the common electrode layer and the data line, and the hollow structure part comprises at least one hollow area.

11. The array substrate as claimed in claim 10, wherein the hollow structure part comprises a plurality of hollow areas;
the plurality of hollow areas are arranged in a matrix.

12. The array substrate as claimed in claim 11, wherein the hollow structure part is in a grid structure.

13. The array substrate as claimed in claim 11, wherein each of the hollow areas is in a circular shape.

14. The array substrate as claimed in claim 10, wherein the hollow structure part comprises one hollow area;
the one hollow area is in a rectangular shape.

15. The array substrate as claimed in claim 10, wherein the hollow area comprised by the hollow structure part meets: for any point on a frame of the hollow area, a minimum value of a distance from it to the frame of the overlapping area is not less than 2 μm.

16. The array substrate as claimed in claim 11, wherein the hollow area comprised by the hollow structure part meets: for any point on a frame of the hollow area, a minimum value of a distance from it to the frame of the overlapping area is not less than 2 μm.

17. The array substrate as claimed in claim 12, wherein the hollow area comprised by the hollow structure part meets: for any point on a frame of the hollow area, a minimum value of a distance from it to the frame of the overlapping area is not less than 2 μm.

18. The array substrate as claimed in claim 13, wherein the hollow area comprised by the hollow structure part meets: for any point on a frame of the hollow area, a minimum value of a distance from it to the frame of the overlapping area is not less than 2 μm.

19. The array substrate as claimed in claim 14, wherein the hollow area comprised by the hollow structure part meets: for any point on a frame of the hollow area, a minimum value of a distance from it to the frame of the overlapping area is not less than 2 μm.

20. The array substrate as claimed in claim 10, wherein the common electrode layer, the gate line and the data line are located in different layers respectively, the array substrate further comprises:
intermediate layers located between the film where the gate line locates and the common electrode layer, and between the film where the data line locates and the common electrode layer; wherein the intermediate layers comprise a passivation layer and/or a resin layer, a material of the passivation layer comprises one or more of silicon oxide and silicon nitride.

21. The array substrate as claimed in claim 11, wherein the common electrode layer, the gate line and the data line are located in different layers respectively, the array substrate further comprises:
intermediate layers located between the film where the gate line locates and the common electrode layer, and between the film where the data line locates and the common electrode layer; wherein the intermediate layers comprise a passivation layer and/or a resin layer, a material of the passivation layer comprises one or more of silicon oxide and silicon nitride.

22. The array substrate as claimed in claim 12, wherein the common electrode layer, the gate line and the data line are located in different layers respectively, the array substrate further comprises:
intermediate layers located between the film where the gate line locates and the common electrode layer, and between the film where the data line locates and the common electrode layer; wherein the intermediate layers comprise a passivation layer and/or a resin layer, a material of the passivation layer comprises one or more of silicon oxide and silicon nitride.

23. The array substrate as claimed in claim 13, wherein the common electrode layer, the gate line and the data line are located in different layers respectively, the array substrate further comprises:
intermediate layers located between the film where the gate line locates and the common electrode layer, and between the film where the data line locates and the common electrode layer; wherein the intermediate layers comprise a passivation layer and/or a resin layer, a material of the passivation layer comprises one or more of silicon oxide and silicon nitride.

24. The array substrate as claimed in claim 14, wherein the common electrode layer, the gate line and the data line are located in different layers respectively, the array substrate further comprises:
intermediate layers located between the film where the gate line locates and the common electrode layer, and between the film where the data line locates and the common electrode layer; wherein the intermediate layers comprise a passivation layer and/or a resin layer, a material of the passivation layer comprises one or more of silicon oxide and silicon nitride.

25. The array substrate as claimed in claim 20, wherein a value of the thickness of the intermediate layer is not less than 2 μm.

26. A display device, comprising an array substrate as claimed in claim 10.

27. The display device according to claim 26, comprising an array substrate as claimed in claim 11.

28. The display device according to claim 26, comprising an array substrate as claimed in claim 12.

29. The display device according to claim 26, comprising an array substrate as claimed in claim 13.
